(19) United States
(12) Patent Application Publication
(10) Pub. No.: US 2009/0002945 A1
(43) Pub. Date: Jan. 1, 2009

(54) Fan Aspirated Sensor

(75) Inventor: Neil Kenny, Ermington (AU)

Correspondence Address: MICHAEL MOLINS;MOLINS & CO., SUITE 5, LEVEL 6, 139 MACQUARIE ST, SYDNEY NSW, 2000, AU

(73) Assignee: Regulator Australia Pty Ltd, Ermington NSW (NL)

(21) Appl. No.: 12/097,870

(22) PCT Filed: Dec. 19, 2006
(86) PCT No.: PCT/AU2006/001919

§ 371 Date: Jun. 17, 2008

(30) Foreign Application Priority Data
Dec. 20, 2005 (AU) 2005907167

(51) Int. Cl. H05K 7/20

(52) U.S. Cl. 361/695

(57) ABSTRACT

Described in this specification is a fan aspirated sensor. The enclosure for the device is equipped with an internal fan and has an air flow channel with suitable inlet and exit opening to cooperate with the ventilation openings in the cover of the enclosure.

### FIELD OF THE INVENTION

The invention relates to wall mounted sensors and more particularly to a low profile, wall mounted sensor enclosure within which an air flow over a sensor is established by a fan.

### BACKGROUND OF THE INVENTION

Wall mounted sensors are used within a wide variety of building structures for the purpose of sensing or measuring temperature, humidity, carbon dioxide or other characteristics of the atmosphere within an enclosed space. A wall mounted sensor normally relies upon a naturally ventilated enclosure, an appropriate sensor being contained within the enclosure. The enclosure relies on external air currents and thus function best when the sensor is somewhat detached from the laminar air flow associated with the wall onto which the sensor is mounted. Thus, prior art enclosures generally extend 30 to 40 mm away from the wall, and have ventilation slots or openings that allow air to circulate into and out of the enclosure. Architects, designers and end users prefer enclosures that are lower in height and with minimal openings because these features contribute to improved (minimal) appearance. However, low profile sensors have suffered in the past from compromised air circulation, resulting in poor or inaccurate sensing.

### OBJECTS AND SUMMARY OF THE INVENTION

It is an object of the invention to provide a fan aspirated sensor that functions at least as well as its higher profile naturally ventilated counterparts.

It is another object of the invention to provide a low profile sensor within which is located a fan.

It is another object of the invention to provide sensors having improved or flexible appearance attributes that do not compromise performance in achieving those attributes.

Accordingly, there is provided a low profile enclosure within which is mounted a sensor and a fan. The fan draws air into the enclosure and over the sensor. Air passing over the sensor is expelled through an opening in the enclosure.

In preferred embodiments, the enclosure defines a distinct air flow chamber within which the sensor is located.

In other embodiments of the invention, the fan assists in removing heat from electronics located within the enclosure.

### BRIEF DESCRIPTION OF THE DRAWING FIGURES

FIG. 1 is an exploded perspective view of a low profile sensor in accordance with the teachings of the present invention;

FIG. 2 is an inverted exploded perspective of the device depicted in FIG. 1;

FIG. 3 is an exploded perspective view of a second embodiment of the invention; and

FIG. 4 is an inverted perspective view of the embodiment depicted in FIG. 3.

### BEST MODE AND OTHER EMBODIMENTS

The invention will now be disclosed with reference to a low profile, wall mounted sensor of the type that might be used, for example, in a residential building to measure temperature. It will be appreciated that the teachings of the present invention particularly with regard to fan aspiration are not limited, in practicality, to any particular enclosure shape or sensor function.

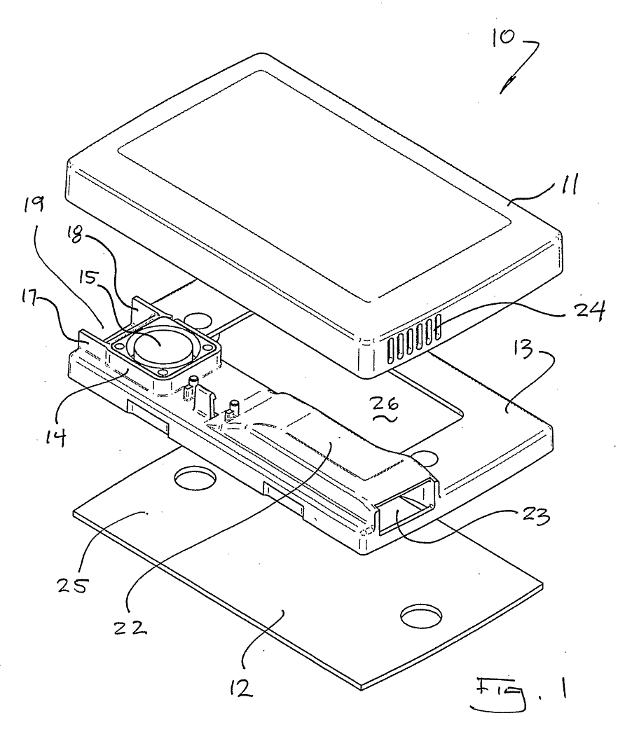

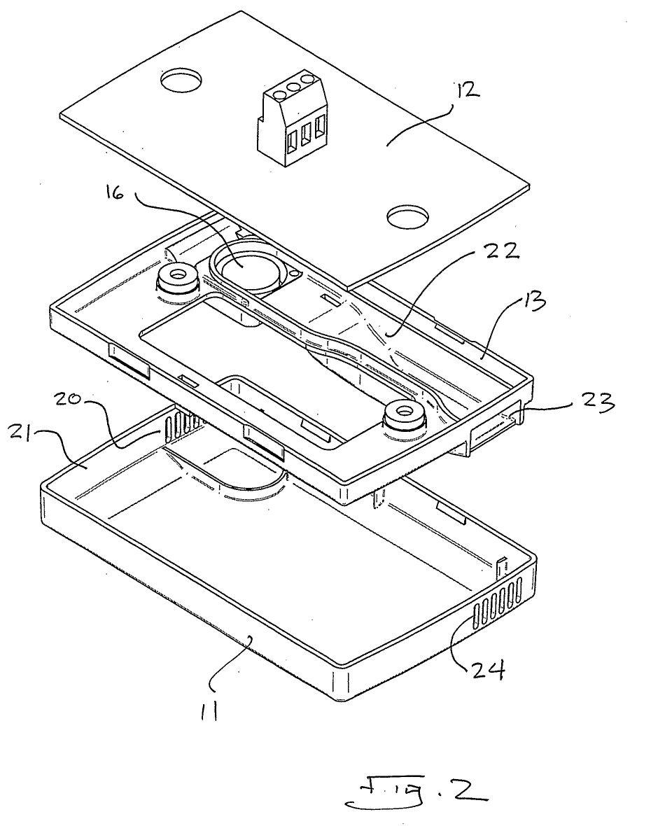

As shown in FIG. 1, a fan aspirated sensor 10 comprises a low profile enclosure defined by a low profile cover 11 and a circuit board 12 that acts as a backing to the cover 11. An intermediate member or chassis 13 is located between the cover 11 and the circuit board 12. The intermediate member 13 comprises a thin moulding that incorporates a fan mount 14 that positions a small electronic fan 15 above an opening 16 (see FIG. 2). The fan mounting 14 further comprises a pair of side walls 17, 18. The side walls 17, 18 define an inlet 19 when the cover 11 is installed. The fan rotates in the plane of the member 13.

With the cover 11 in place, the fan 15 operates to draw air through a series of first ventilation openings 20 located on one end 21 of the cover 11, preferably the first ventilation openings 20 are positioned next to the inlet 19. Air is thus drawn by the fan into the first vents 20, through the inlet 19 and then expelled into an air flow channel 22 that is, for example, integral with the intermediate member 13. This channel 22 forms a conduit for the flow of air when its otherwise open underside is sealed by the circuit board 12 during assembly. Air blown into the conduit by the fan 15 is discharged through an exit opening 23 located at one end of the intermediate member 13. The air flow channel 22 is preferably located between the inlet 19 and the exit opening 23. The channel may be moulded into the cover or chassis or may be formed separately and incorporated into the fan's flow path anywhere under the cover 11. Discharged air then passes through a series of second vent openings 24 located on an opposite end of the cover 11. Preferably the series of second vent openings 24 is positioned next to the exit opening 23.

It will be appreciated than any sensor located on an upper surface 25 of the circuit board 12 that is positioned within the confines of the walls of the conduit 22 will be exposed to the continuous flow of room air that is drawn into the enclosure by the fan 15. Electronic components located on the circuit board 12 within the walls of the conduit can be cooled by this same air flow.

In the examples depicted in the drawing figures, the intermediate member 13 also comprises a central opening 26 that allows graphic displays such as LED displays mounted on the circuit board 12 to be viewed through the cover 11 when particular cover configurations (not shown) are used. The same opening 26 allows switches mounted on the circuit board 12 to be activated when specially adapted covers 11 are utilised.

It will be appreciated that in the example provided, the fan 15 draws air from one side of the intermediate member 13 and delivers it into the conduit located on the obverse side of the intermediate member 13. Similarly, it will be appreciated that the example pertains to a rectangular enclosure having intake and discharge vents 20, 24 located at opposite longitudinal ends.

In the above examples, the intermediate member 13 and the circuit board are two layers of a chassis. In other embodiments, the chassis may only comprise one single layer, on which some or all of the features and components carried by the two layers (the intermediate member and the circuit board) are located. In further other embodiments, the device is directly mounted on the wall without a chassis. In these examples, the components employed by the device are carried by the cover itself.

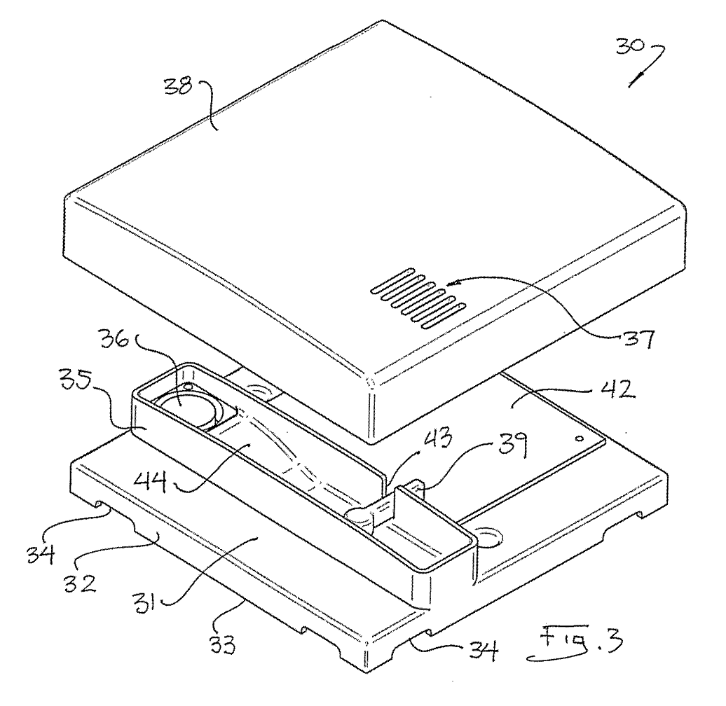

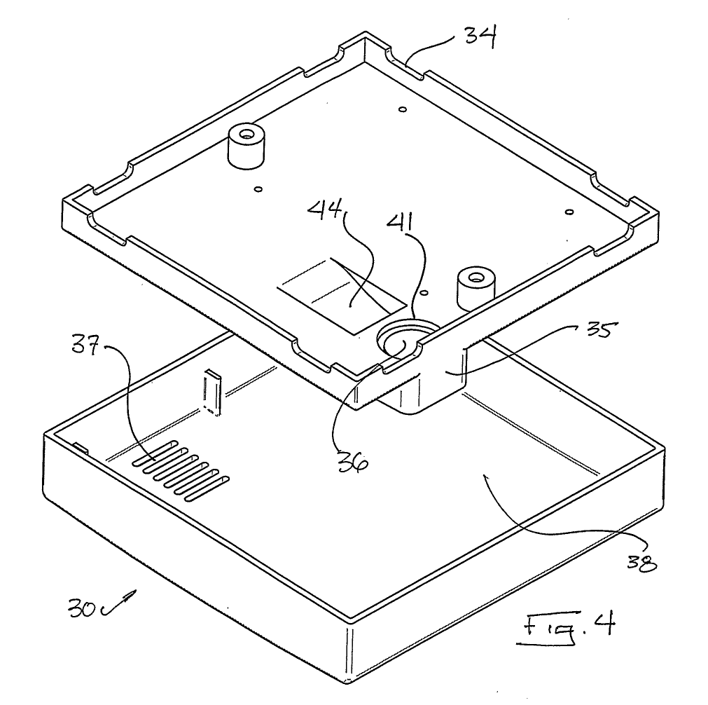

FIGS. 3 and 4 illustrate a second embodiment that provides the characteristics and benefits of the present technology. As shown in FIG. 3, a low profile aspirated sensor 30 comprises a moulded base 31 having a peripheral rim 32. The terminal edges 33 of the rim 32 have recessed exhaust vents 34, in this example two along each edge of the base 31. The base moulding further comprises an open topped channel 35 in which is located an intake fan 36. Air entering the channel 36 passes through an intake vent 37 located on the front or major surface of the cover moulding 38. The under side of the cover moulding 38 seals the open top of the channel 35. Air enters through the intake vent 37 and passes over a sensor 39. Air drawn through the vents 37 continues toward the fan 36. The fan 36 discharges the incoming air through a hole in the base moulding 41, this air then being exhausted through the vents 34. In this example, the sensor 39 is attached to and associated with a circuit board 42 that is carried on the surface of the base moulding 31. In this example, the side wall of the channel 35 includes a small notch 43 for receiving the sensor. Also note that the floor 44 of the base moulding slopes upwardly so that the fan 36 may be positioned with its upper surface generally in smooth alignment with the channel floor 44.

These and other design details may be varied according to the technical and aesthetic requirements of the user and should be understood as having been provided as examples and not as limitation to the scope of spirit of the invention.

What is claimed is:

1. A low profile, wall mounted fan aspirated sensing apparatus, comprising:
a cover;
a sensor and
an electric fan concealable by the cover;
the fan drawing air into the cover and in proximity to the sensor that is located in a flow path of the air within the cover.

2. The apparatus of claim 1, wherein,
the cover further has formed in it a ventilation opening through which air is drawn by the fan.

3. The apparatus of claim 1, wherein,
the fan is located in a channel within which the sensor is located.

4. The apparatus of claim 1, wherein,
the flow path is defined by a moulded channel.

5. The apparatus of claim 4, wherein,
the channel is at least in part defined by the cover.

6. The apparatus of any one of claims 1 to 5, wherein,
a front surface of the cover defines a plane, and the fan rotates parallel to this plane.

7. The apparatus of any one of claims 1-6, wherein,
the cover further comprises a rim positioned around the fan, the rim guiding an air flow into a direction of the flow path.

8. The apparatus of any one of claims 1 to 7, further comprising,
a backing, the backing being a circuit board on which the sensor and the fan are mounted.

9. A low profile, wall mounted fan aspirated sensing apparatus, comprising:
a cover;
a base plate;
a sensor and an electronic fan mounted on the base plate;
the fan drawing air into the cover over the base plate and in proximity to the sensor.

10. The apparatus of claim 9, wherein,
the base plate defines, at least in part, a channel in which the sensor is located.

11. The apparatus of claim 9, wherein,
the base plate cooperates with the cover to define a channel, the fan being positioned in the channel.

12. The apparatus of claim 11, wherein,
the fan draws air through an intake vent in the cover and exhausts air through one or more exhaust vents in the base plate.

13. The apparatus of claim 12, wherein,
the channel has an inclined floor.

14. The apparatus of any one of claims 9-13, wherein,
the base plate has a peripheral rim having one or more recesses that define exhaust vents.

15. The apparatus of any one of claims 9 to 14, wherein,
the base plate has a circuit board mounted on it, the circuit board having a sensor that extends into the channel.

16. The apparatus of any one of claims 9 to 15, wherein,
the cover seals the channel and forms at least a portion of the channel.

17. The apparatus of any one of claims 12 to 16, wherein,
the fan exhausts through an opening formed in the base plate.

18. The apparatus of claim 1, wherein,
a channel is carried by an intermediate member that defines a channel to form a conduit for an air flow.

19. The apparatus of claim 18, wherein,
the backing is a circuit board on which the sensor and the fan are mounted.
